(19) United States
(12) Patent Application Publication
(10) Pub. No.: US 2021/0140767 A1
(43) Pub. Date: May 13, 2021

(54) INERTIAL DEVICES WITH WAFER-LEVEL INTEGRATION OF HIGHER DENSITY PROOF MASSES AND METHOD OF MANUFACTURING

(71) Applicant: SOCIETE DE COMMERCIALISATION DES PRODUITS DE LA RECHERCHE APPLIQUÉE SOCPRA SCIENCES ET GÉNIE S.E.C., Sherbrooke (CA)

(72) Inventors: Andre DOMPIERRE, Sherbrooke (CA); Luc FRECHETTE, Sherbrooke (CA)

(21) Appl. No.: 16/623,163

(22) PCT Filed: Jun. 18, 2018
(86) PCT No.: PCT/CA2018/050736

§ 371 Date: Dec. 16, 2019

Related U.S. Application Data
(60) Provisional application No. 62/520,751, filed on Jun. 16, 2017.

(51) Int. Cl. G01C 19/5656; G01C 19/5663; B81B 3/00

(52) U.S. Cl. CPC G01C 19/5656; G01C 19/5663; B81B 2203/0118; B81B 2201/0235; B81B 3/0018

(57) ABSTRACT

An inertial device comprises a frame. A cantilever beam has a first end connected to the frame and a second end cantilevered relative to the frame, the cantilevered beam forming a spring portion between the first end and the second end, the cantilever beam having a support surface defining a support area. The frame and the cantilever beam are made from a support wafer, the support wafer being made of silicon, a thickness of the support wafer at the support area ranging between 0 μm and 800 μm. A mass bonded to the support surface of the silicon wafer at the support area, the mass being made of tungsten, a thickness of the mass being of at least 20 μm.

### CROSS-REFERENCE TO RELATED APPLICATION

The present application claims the priority of U.S. Provisional Patent Application No. 62/520,751, filed on Jun. 16, 2017 and incorporated herein by reference.

### TECHNICAL FIELD

The present application relates to inertial devices having proof masses in microelectromechanical systems (MEMS) and to processes for manufacturing same.

### BACKGROUND OF THE ART

Silicon-based inertial devices like microelectromechanical systems (MEMS) accelerometers and gyroscopes are now widely adopted in consumer electronic products. They however have limited performances compared to macro-scale devices at low g accelerations and low frequencies, especially in terms of background noise and resolution. This may have limited their market penetration for some applications such as seismology, human activity monitoring, asset tracking and structural health monitoring. In addition, MEMS vibration energy harvesters are considered as an emergent solution to power the Internet of Things (IoT) and wireless sensor networks, but they currently must be relatively large to produce enough power.

In such applications, the limitations are partly due to the small size of MEMS and the relatively low material density of their silicon proof masses. Indeed, the sensitivity and minimal resolution of inertial MEMS depend on several factors including the transducer and read-out circuit design, but also on the size of the mass. Larger bulk micromachined silicon based devices are an explored solution, but they yield increased device footprints and thus higher costs per unit.

An alternate solution is to integrate materials with a density larger than silicon (ρ_{Si}=2.33 g/cm³) to produce the proof mass. Among common metals, gold has a greater density (ρ_{Au}=19.3 g/cm³) and can readily be electrodeposited. Gold is however expensive and has a large mismatch in coefficient of thermal expansion compared to silicon (CTE=14 vs 3). Tungsten, which also has a greater density than silicon (ρ_{W}=19.25 g/cm³=8.3×ρ_{Si}) offers a better CTE match (CTE=4) and is more cost effective. It is also compatible with MEMS and CMOS microelectronic processes. For these reasons, it is a more attractive option, although thick layers cannot be electroplated.

Screen printed masses can be made from tungsten nanoparticles filled polymer paste, but their actual density is about 50% of bulk tungsten. This density is slightly higher but comparable to nickel and copper (ρ_{Ni/Cu}=8.9 g/cm³), which can both be electroplated. Tungsten can also be integrated using thin film deposition, such as metal organic chemical vapor deposition (MOCVD), but this may limit the potential thickness of the masses. This constraint can be circumvented by using a silicon mold structured with thin pillars or etched wells and filling it with tungsten via conformal MOCVD. The resulting mass thickness may be less than what can be achieved by bulk silicon microfabrication. In contrast, producing masses of similar thicknesses that preserve an effective density close to bulk tungsten would require challenging aspect ratios by deep reactive ion etching (DRIE).

### SUMMARY

It is an aim of the present disclosure to provide microelectromechanical systems (MEMS) with higher density proof masses.

It is a further aim of the present disclosure to provide processes for integrating higher density proof masses at wafer level for use in microelectromechanical systems (MEMS).

Therefore, in accordance with the present disclosure, there is provided an inertial device comprising: a frame, a cantilever beam having a first end connected to the frame and a second end cantilevered relative to the frame, the cantilevered beam forming a spring portion between the first end and the second end, the cantilever beam having a support surface defining a support area, wherein the frame and the cantilever beam are made from a support wafer, the support wafer being made of silicon, a thickness of the support wafer at the support area ranging between 10 μm and 800 μm; and a mass bonded to the support surface of the silicon wafer at the support area, the mass being made of tungsten, a thickness of the mass being of at least 20 μm.

Still further in accordance with the present disclosure, a bond layer is for instance between the cantilever beam and the mass.

Still further in accordance with the present disclosure, the bond layer is for instance one of an epoxy-based bond layer and a metallic bond layer.

Still further in accordance with the present disclosure, a hard mask may be between the support area and the mass of tungsten.

Still further in accordance with the present disclosure, the hard mask has for instance a layer of SiO₂.

Still further in accordance with the present disclosure, the hard mask has for instance a layer of Si₃N₄.

Still further in accordance with the present disclosure, a hard mask may be mounted to a surface of the mass away from the support area.

Still further in accordance with the present disclosure, the hard mask has for instance a layer of SiO₂.

Still further in accordance with the present disclosure, the hard mask has for instance a layer of Si₃N₄.

Still further in accordance with the present disclosure, a piezoelectric layer may be on the support surface of the cantilever beam.

Still further in accordance with the present disclosure, a hard mask may be on a surface of the piezoelectric layer facing away from the support area.

Still further in accordance with the present disclosure, an electrode layer may be on the surface of the piezoelectric layer facing away from the support wafer.

Still further in accordance with the present disclosure, a contact connector is provided for instance through the hard mask and in contact with the electrode layer.

Still further in accordance with the present disclosure, the hard mask has for instance a layer of SiO₂.

Still further in accordance with the present disclosure, the hard mask has for instance a layer of Si₃N₄.

Still further in accordance with the present disclosure, the support wafer is for instance a silicon on insulator wafer having two layers of silicon separated by an insulator.

Still further in accordance with the present disclosure, at least one cap is for instance mounted to the frame and encapsulating the mass.

Still further in accordance with the present disclosure, lateral surfaces of the mass project for instance from the support surface in a non-perpendicular direction.

Still further in accordance with the present disclosure, the lateral surfaces have for instance irregular etched geometries.

Still further in accordance with the present disclosure, a footprint of the mass ranges for instance from 50% to 80% of the footprint of the frame.

Still further in accordance with the present disclosure, a footprint of the frame is for instance at most 1.0 cm².

Still further in accordance with the present disclosure, the spring portion of the cantilever beam is for instance thinner than the frame and than a portion of the cantilever beam defining the support area.

Still further in accordance with the present disclosure, a thickness of the spring portion is for instance between 10 and 50 μm.

Still further in accordance with the present disclosure, the frame and cantilever beam are for instance monoblock from the support wafer.

### DESCRIPTION OF THE DRAWINGS

FIG. 1 is a schematic view of a process for integrating higher density proof masses with silicon at the wafer level, in accordance with a first embodiment of the present disclosure;

FIG. 2 is a AFM scan of a polished tungsten substrate. A 1.09 nm RMS roughness and a 13.4 nm maximum height profile were measured on this sample;

FIG. 3 are photographs of the proof masses at various steps of the process of FIG. 1: (a) hard mask remains in good condition; (b) partially milled W wafer after 2nd immersion, with the hard mask shows signs of damages; (c) fully released W masses on Si. The outer part of the W wafer was purposely removed for easier handling;

FIG. 4 are photographs of a fabricated device showcasing a perspective view of the full die (a), as well as a side (b) and top view (c) of a cantilever with a thick W mass;

FIG. 5 is a photograph of an experimental setup for Q-factor measurement (a) and recorded data with the fitted envelope (b);

FIG. 6 is a flow chart providing a comparative view of the process of FIG. 1 with variations;

FIG. 7 is a schematic view of a process for integrating higher density proof masses with silicon at the wafer level, in accordance with a second embodiment of the present disclosure, with hard masks on both sides of the proof mass;

FIG. 8 is a schematic view of a process for integrating higher density proof masses with silicon at the wafer level, in accordance with a third embodiment of the present disclosure, with SOI wafer;

FIG. 9 is a schematic view of a process for integrating higher density proof masses with silicon at the wafer level, in accordance with a fourth embodiment of the present disclosure, integrating a piezoelectric material;

FIG. 10 is a schematic view of a process for integrating higher density proof masses with silicon at the wafer level, in accordance with a fifth embodiment of the present disclosure, for an in-plane transducer;

FIG. 11 is a schematic view of a process for integrating higher density proof masses with silicon at the wafer level, in accordance with a sixth embodiment of the present disclosure, from a thinned down silicon wafer;

FIG. 12 is a schematic view of a process for integrating higher density proof masses with silicon at the wafer level, in accordance with a seventh embodiment of the present disclosure, with dry etching used to pattern the masses;

FIG. 13 is a schematic view of a process for integrating higher density proof masses with silicon at the wafer level, in accordance with an eighth embodiment of the present disclosure, with a variation in bonding method;

FIG. 14 is a schematic view of a process for integrating higher density proof masses with silicon at the wafer level, in accordance with a ninth embodiment of the present disclosure, with silicon layer grown on top of the proof mass substrate;

FIG. 15 is a schematic view of an inertial device using the wafer and proof mass made using the processes described in FIGS. 1 to 14 and 16; and

FIG. 16 is a schematic view of a process for integrating higher density proof masses with silicon at the wafer level, in accordance with a tenth embodiment of the present disclosure, a pair of caps encapsulating the proof mass.

Unless stated otherwise, the schematic figures of the process and of the devices are not to scale.

### DETAILED DESCRIPTION

Referring to FIG. 1, there is shown a process 10 for integrating higher density proof masses with silicon at the wafer level, in accordance with an embodiment of the present disclosure. The process is used to fabricate an assembly featuring a wafer 1 with proof mass 2 or proof masses 2, as generally shown at the outset of the process. For consistency, the expression proof mass is used in the singular, but the processes described herein may have a single wafer 1 having a plurality of proof masses 2 dispersed thereon. Hence, the process, and other processes described herein may include additional steps to separate the wafer 1 with masses 2 in a plurality of inertial devices each having a portion of the wafer 1 and one or more masses 2 thereon, such as the one shown in FIG. 15 and described in further detail hereinafter. The expression “wafer” is used, but other expressions may include substrate. Moreover, the expression “assembly” is used to reference to the wafer 1 and proof mass 2. The wafer 1 and proof mass 2 form an integral component or assembly, and other layers may also be present in the assembly. For example, the assembly may also have a bond layer 3 between the wafer 1 and the proof mass 2. The assembly may also have hard masks, with one or more layers, such as hard mask layers 4 and 5. The hard mask layer 4 may for example be a silicon dioxide mask, and the hard mask layer 5 may be a silicon nitride mask. Other components may include a piezoelectric material layer 6 (FIG. 9), for instance used as a transducer, an electrode layer 7 (FIG. 9), contact connectors or pads 8 for interfacing the electrode layer 7 with circuitry (e.g., wires), and/or a cap 9 (FIG. 11), for wafer level device packaging.

Functional wafer 1 is fabricated by forming geometries, for example springs, in a silicon substrate, whereas the higher density proof masses 2 are wafer bonded. The proof masses 2 may be patterned by a 2-step wet chemical milling approach compatible with many common cleanroom materials. According to an embodiment, the proof masses 2 are made from tungsten (W) (e.g., made from 500 μm thick tungsten substrates or wafers), although other metals can be used as discussed below. Therefore, for the sake of simplicity, reference is made to W, although proof masses 2 may be made in other materials as well. The process 10, and subsequently described processes, may generally be separated in three groups of steps: A) W and Si wafers pre-bonding preparation; B) wafer bonding; and C) mass and cantilever definition and release.

A) Pre-Bonding Wafer Preparation

In an embodiment of the pre-bonding wafer preparation, as shown at 1) in FIG. 1, a tungsten substrate (W wafer), for example having a 100 mm diameter, or up to 200 m, a 500 μm thickness and 99% purity, may be polished on both sides to get a mirror surface finish. The polishing may result in a thinning of the tungsten substrate, with for example a final thickness after polishing of 440 μm and a typical surface roughness of less than 4 nm root mean squared (RMS), as measured by atomic force microscopy (AFM) and shown in FIG. 2. Before further processing, the metal wafer may further be cleaned for instance using standard solvent cleaning methods. The metal wafer may then be water rinsed until exhibiting clean, hydrophilic surfaces.

According to 2) in FIG. 1, a hard mask (e.g., 100 nm Si₃N₄ on a 1 um SiO₂) layer stack may then deposited on a top surface of the tungsten wafer by plasma enhanced chemical vapor deposition (PECVD). This hard mask may for example be patterned by successive lithography and CF4 fluorine reactive-ion-etching (RIE).

According to 3) of FIG. 1, a photoresist mask is then patterned on the undersurface of the tungsten wafer. As an example, the photoresist mask may be a 15 μm-thick KMPR® photoresist mask laid on the underside of the metal wafer and patterned by photolithography with a front to back alignment.

According to 4) of FIG. 1, prolonged deep isotropic wet etching may then be realized on both sides of the tungsten wafer to begin the partial definition of the masses, as a result of the presence of the masks of 2) and 3). The deep isotropic wet etching may be performed using a buffered potassium ferricyanide based etchant. To increase the etch rate and improve uniformity, the solution may be heated (e.g., to about 60-70° C.) and stirred using nitrogen bubbling. Moreover, the substrate may be inspected and rotated every 20 min. At this temperature, the measured etch rate is approximately 0.5 μm/min across the wafer. FIG. 3(a) shows a partially defined tungsten wafer after 2 h 20 min of etching. The target for the first tungsten etching step of 4) is to keep approximately 100 μm of thickness for robust handling of the mass wafer. In particular conditions, this was achieved by an immersion time of about 5 h when simultaneously etching on both sides. However, etching for this long is not possible with the photoresist mask applied at 3) due to delamination after cumulated immersion. Meanwhile, the nitride hard mask of 2) remains relatively intact. Hence, the process of FIG. 1 can be modified to use the same hard mask on both sides to avoid the delamination of a photoresist mask, as described in subsequent variations below, such as in FIG. 7. By doing so, the immersion time of the double-sided etch can be increased further and consequently, the required post-bond etching time can also be reduced, as well as the overall process time.

In parallel, the silicon wafer 1 is prepared ahead of the group of bonding steps B). Spring patterns, i.e., parts of the silicon wafer 1 of reduced thickness in contrast to a remainder of the silicon wafer 1, may be realized by photolithography and a subsequent deep reactive ion etching (DRIE), as shown in 5) of FIG. 1, with an appropriate photoresist mask delimiting the spring patterns. The etching depth may vary according to the device specifications, desired beam thickness (typically 10 to 50 um), and initial Si wafer thickness. Accordingly, at the outset of A), a proof mass with partial wafer patterning is obtained (a.k.a., tungsten wafer) as in 4), as well as the silicon wafer with patterning as in 5).

B) Wafer Bonding

As shown at B), the wafer stack is assembled from the wafers of A) using an intermediate adhesive layer for convenience. Due to the topologies created during the previous tungsten wet etch step of the pre-bonding preparation, a roller based resist transfer method may be used to apply the resist/adhesive on the patterned substrate, as shown in 6) of FIG. 1. In an embodiment, a bond layer 3 (e.g., a 15 μm thick SU8 layer) is first spun on a support wafer. A roller (such as a Teflon® coated roller) is then rolled on the support wafer and/or rolled over the tungsten wafer 2 onto mask layers 4,5 (e.g., FIG. 7) to transfer part of the resist. The thickness of the film transferred on the patterned tungsten substrate may vary (e.g., approximately 10 μm), but the resist is not required to be smooth or uniform. As the masses 2 are not subject to stresses during the device operation, the bond layer 3 may only need to resist to the remaining process steps and to the temperature of operation of the device. Other bonding approaches may be applicable as described below.

Then, as shown in 7) of FIG. 1, the silicon and tungsten wafers 1,2 are optically aligned and bonded, by way of the resist or bond layer 3. The alignment may be achieved on a mask aligner, such as a EVG620 aligner, before transferring aligned wafer stack in a wafer bonder, like the EVG501 bonding tool for example. A force may be applied (e.g., 1 kN) for instance by heated chucks, for example heated to 200° C. for 20 min. At the outset of B), the wafer stack of 7) is obtained.

C) Mass and Cantilever Definition and Release

To complete the patterning and release of the masses, the assembled wafer stack may be re-immersed in the tungsten etchant in 8) of FIG. 1, for example in similar conditions as before. During this step, only the top of the tungsten substrate is exposed and etched. In an example, the substrate was initially immersed for 2 h 40 min and, as shown in FIG. 3(b), was partially etched through in the same areas. The hard mask was however partially attacked, suggesting a degraded selectivity following the bonding step. An additional 3.5 h of etching were necessary to remove all metal in the desired areas. The wafer was then immersed for another 2 h to overetch the sides of the masses, mainly to reduce the knife edges and also compensate for slight etch anisotropy. FIG. 3(c) shows the fully released bonded tungsten masses on the silicon wafer after this step.

In an exemplary embodiment, neither the silicon wafer 1 nor the bond layer 3 were etched, due to the compatibility of the etchant with the silicon and bond layer. The solution did not significantly etch Cr, SiO₂ and Si₃N₄, although a slight increase of the surface roughness may be observed. Meanwhile, Cu turned to a dark brown and the layer thickness increased, suggesting oxidation of the surface. A 150 nm thick Al layer was also etched by the solution in about 15 min, which is a slower rate than the target metal (50:1 selectivity). Exemplary observations are presented in Table 1.

TABLE 1
W etchant effects on common materials at 60° C.

| | Etch Rate | |
|---|---|---|
| Material | (nm/min) | Comments |
| W | ≈500 | Sensitive to agitation |
| Cu | ↑ thick | Copper oxide formation |
| Al | ≈10 | |
| Cr | — | Slight roughness increase |
| Si | — | No visible etch |
| SiO₂ (PECVD) | ≤0.1 | Slight roughness increase |
| | | Long immersion forms pin holes |
| Si₃N₄ (PECVD) | ≤0.1 | Slight roughness increase |
| | | Long immersion forms pin holes |
| SU8 (uncured) | Not meas. | Dissolves in solution |
| SU8 (cured) | — | No visible etch |
| KMPR | — | Delaminates if long immersion |

Moreover, based on the etching patterns observed on the hard mask during the second etching stage (post-bond), friction with the bonding tool or ionic contamination from the bonding glass may cause a degradation of the mask selectivity.

According to 9) and 10) of FIG. 1, the process 10 aims to complete the cantilevered structures, by way of a backside DRIE. A temporary carrier scheme may be used as in 9) of FIG. 1 to accommodate the thick tungsten masses on the front side. To do so, thick films of a temporary bond layer, such as Crystal Bond 509, may be applied on the carrier wafer, such as a double side polished fused silica wafer, as well as on top of the tungsten masses/silicon wafer. In this example, the clear adhesive flows at 120° C. and is acetone soluble, allowing easy removal and additional lithography steps if needed. Following application, the temporary bond layers (on the silicon wafer and the carrier wafer) are heated, put in vacuum to remove bubbles or voids and finally put in contact to complete the temporary bond. Since the carrier wafer and adhesive are clear in this example, a resist mask may be defined by photolithography using a front to back alignment. An oxide mask could however be used to avoid this step altogether, as described in subsequent variations, for instance as in FIG. 8. Once the mask is developed, the wafer stack is inserted in an inductive coupled plasma chamber, such as the ASE-STS tool, to proceed with the backside silicon DRIE, as in 10) of FIG. 1.

After full etching of the silicon beams, as per 11) of FIG. 1, the temporary assembly may also be used for device dicing. The separated dies may then be released from the carrier by immersion in a solvent, such as an acetone bath for example. Finally, the assembly may be cleaned in deionized (DI) water and dried. The exemplary of the assembly, shown as a fabricated device presented in FIG. 4 has a footprint of 1.74 cm².

To avoid contamination of the tools, the beam release may not be completed during the backside DRIE. The last 50 μm may be etched in a diluted KOH bath at room temperature. However, this step may lead to device failures as the Crystal bond and SU8 bond are sensitive to diluted KOH solution. Improved yield may be achieved if the beam release is done by a through-wafer DRIE step down to an etch stop layer instead, using a silicon on insulator (SOI) wafer, as described in subsequent variations for instance as in FIG. 8.

Device Characterization

Referring to FIG. 4, the assembly 1 resulting from the process 10 or variations thereof is characterized dynamically to showcase the potential for wafer-level fabrication of very sensitive, low frequency MEMS harvesters/inertial sensors (MEMS harvester included in inertial sensors). In FIG. 5(a), the assembly 1 is glued to a carrier board and mounted on a shaker to evaluate its Q-factor and its resonant frequency. The experimental setup shown in FIG. 5(a) consists of an electromagnetic shaker and a laser probe. The assembly 1 is brought into resonance by the shaker and once the steady-state is reached, the shaker is turned off and the decaying laser probe signal is used to evaluate the Q-factor by the logarithmic decrement method, as shown in FIG. 5(b). A non-linear curve fitting algorithm may then be used to extract the value of Q. For the device tested, a resonant frequency fₙ=87.2 Hz was measured and Q=267 was estimated based on the average of 5 data sets.

Therefore, the process 10 is used to integrate high density tungsten proof masses 2 in MEMS inertial devices at the wafer level for the wafer 1, in contrast to silicon proof masses. The thickness of tungsten resulting from the process 10 and from subsequently described processes of the present disclosure may be of at least 20 μm, i.e., substantially thicker than other proof masses manufactured by chemical vapor deposition techniques. For example, the thickness may range from 20 μm to 500 μm. In contrast, the thickness of the silicon wafer 1 may range from 10 μm to 800 μm. As shown in all embodiments herein, the mass 2 is on a support area of the silicon wafer 1 that forms a fraction of the overall support surface of the silicon wafer 1. For example, a footprint of the mass 2 may range from 50% to 80% of the footprint of the inertial device then diced from the support wafer 1, as shown subsequently in FIG. 15. The support wafer 1 may be circular, with a diameter of 200 mm, with the diced inertial device generally being at most 1.0 cm² in footprint. The heterogeneous integration scheme described in the present application, which may combine wet chemical etching of a high density metallic substrate 2 with wafer bonding on a silicon substrate 1, leverages the strength of both materials to fabricate dense masses and high quality springs. Through the process 10, an exemplary device with a footprint of 1.74 cm² and a low resonant frequency of 87.2 Hz was fabricated and showcased a Q-factor of 267 in ambient air. The process 10 was validated for fabrication of out of plane transducers, but may also be used to produce in-plane transducers without major modifications.

The use of wet chemical milling is challenging in terms of dimensional control in addition to limiting the minimum feature sizes, which is dictated by the mass wafer thickness. However, these concerns are mitigated by the fact that the mass in MEMS harvesters and inertial sensors is typically the biggest component in the device. Moreover, adopting tungsten wafers instead of silicon to fabricate the proof masses 2 can reduce the die size or improve sensitivity by almost an order of magnitude, directly impacting cost and opening market opportunities. Although adhesive wafer bonding is used here, the process 10 could also work with other bonding methods, namely eutectic or thermocompressive bonding using intermediate metallic layers patterned with a shadow mask for instance, or even direct bonding (fusion bonding) using very smooth, flat and clean surfaces, such as Si, SiO₂ or Si₃N₄ for example. As observed from FIG. 1 and from other embodiments herein, the lateral walls of the mass 2 may not be perpendicular to the plane of the support surface of the silicon wafer 1. For example, non-straight, irregular and/or non-perpendicular geometries such as knife edges, scallops may be present for the lateral side surfaces or side walls of the mass 2, as a result of the fabrication process.

Variations

While tungsten is described for the proof mass 2 as an example in the process 10, table 2 provided below identifies various metals that could be used, as per their densities greater than silicon. Process variations may have the following characteristics:

A thick metallic substrate is patterned to produce high density proof masses 2 at the wafer 1 level. In the MEMS field, a metal is typically considered thick for layers that are over 10 μm thick, although it may be desirable to use substrates that are 100 μm thick or more to add more mass.

The metallic substrate is composed of a pure material (or an alloy) which has a high density compared to silicon (in kg/m³). For example, the substrate could be made from one of the material contained in Table 2, which compares their density relatively to that of silicon.

TABLE 2
Density of several high density materials

| | Density | Relative density |
|---|---|---|
| Metal | (kg/m³) | (to Si) |
| Iridium | 22650 | 9.7 |
| Osmium | 22610 | 9.7 |
| Platinum | 21400 | 9.2 |
| Rhenium | 21000 | 9.0 |
| Tungsten | 19600 | 8.4 |
| Gold | 19320 | 8.3 |
| Tantalum | 16400 | 7.0 |
| Hafnium | 13310 | 5.7 |
| Ruthenium | 12450 | 5.3 |
| Rhodium | 12410 | 5.3 |
| Palladium | 12160 | 5.2 |
| Thallium | 11850 | 5.1 |
| Lead | 11340 | 4.9 |
| Silver | 10490 | 4.5 |
| Molybdenum | 10188 | 4.4 |
| Bismuth | 9750 | 4.2 |
| Copper | 8940 | 3.8 |
| Nickel | 8908 | 3.8 |
| Iron | 7850 | 3.4 |
| Silicon | 2330 | 1 |

Among the materials listed above in table 2, only a few are cost effective. Many are rare or precious metals which cost several orders of magnitude more than silicon. Other materials cannot be used for different reasons (e.g., lead is banned due to its detrimental effect on the environment, bismuth has a low melting point which is challenging for back end processing).

Tungsten may be bought at a reasonable cost and has a significant advantage over silicon (>8 of relative density). Although they have a lower relative density (<4.5) which make them less attractive, other cost effective metals could be used as well, such as molybdenum, copper, nickel, iron, manganese, zinc.

As shown in the process 10 in FIG. 1, and in the following process examples, the metallic substrate 2 is integrated with a silicon wafer 1 (by bonding with bond layer 3) or with an additional layer (by growth or deposition on the metallic substrate). Due to its material properties (strength), silicon is used as the material for mechanical support of the mass 2 and to fabricate springs for the inertial device. It may also be used to fabricate capacitive transducers if it is the chosen transduction method.

Referring to FIGS. 6 to 14 and 16, variations of the process 10 of FIG. 1 are shown, with the flowchart of FIG. 6 illustrating different characteristics of the variations. Referring to FIG. 7, there is shown a process 70 with adhesive wafer bonding. The processes 10 and 70 are essentially similar, but with a modification in the metallic substrate masking scheme, where a SiO₂/Si₃N₄ hard mask is used on both sides instead of the photoresist in 3) of FIG. 1. This modification is introduced to alter the masking during the first prolonged wet etching step.

FIG. 8 shows a process 80, resembling the processes 70 (FIG. 7) and 10 (FIG. 1), with variations. A first variation is the usage of a SOI wafer in 1) of FIG. 8 to vary the dimensional control on the beam thickness over the wafer. A second variation is the metallic bonding interface used as the bond layer 3 instead of an adhesive between the mass wafer 2 and the functional wafer 1, as in 5) of FIG. 8. As yet another possibility, direct bonding between the SiO₂ hard masks 4 or Si₃N₄ hard masks 5 could be used as well as an alternative to the metallic bonding interface 3 if sufficiently smooth and clean surfaces can be achieved. These variations are proposed to improve the bond robustness to stress and temperature variations. A third variation may consist in using a pre-patterned SiO₂ hard mask on the back of the SOI wafer instead of using a photoresist in 3) of FIG. 8. This alternate approach replaces the necessary lithography step between the temporary carrier mounting and the DRIE that are shown in 10) of FIG. 1 and 9) of FIG. 1. It is pointed out that only one or two of these variations could be incorporated to produce several variants to the process 80. An electrode 7 may also be added at 5).

The processes 90 of FIG. 9 and 100 of FIG. 10 can be grouped with the process 80 of FIG. 8 due to their similarities in terms of mass patterning, bonding approach and the functional wafer used. The process 90 of FIG. 9 builds on the process 80 of FIG. 8 by adding intermediate steps to integrate a piezoelectric material 6 at 2), to be used as an alternative to capacitive transducers. The process 100 is generally the same as the process 80, but showcases an in-plane transducer instead of an out-of-plane transducer which can be fabricated by changing the mask patterns. Thus, different applications could be addressed. Bearing in mind that, as with the processes 80 and 100, the process 90 can also produce in-plane transducers if the mask pattern is designed accordingly. Moreover, these added steps could be integrated to the other processes to convert most of them to piezoelectric transduction. Moreover, an electrode layer(s) 7 may be added at 3), for instance as titanium or chromium. At 9), a contact connector 8 may be added to interface the electrode layer 7 to a circuit.

The process 110 of FIG. 11 differs from the process 80 of FIG. 8 because a thinned down silicon wafer may be used to fabricate the beams instead of a DRIE step. Moreover, the process 110 adds cap wafers 9 for wafer level packaging and a carrier wafer is not required for the beam etching step. The cap wafer 9 may have a same bonding plane as the bonding plane for the mass 2, as shown in FIG. 11. Moreover, although a metallic bonding interface 3 is shown (e.g., Ti/Cu), it is considered to fusion bond the cap 9 to the functional layer 1 or to the SiO₂ hard mask 4 or Si₃N₄ hard mask 5 as well.

The process 120 of FIG. 12 differs from the first six processes because dry etching is used to pattern the masses. Here, the material of the hard mask 4 is presented as aluminum, although SiO₂ may also be used similarly to the previously presented processes, or even or alumina (Al₂O₃). The process 130 of FIG. 13 is similar to the process 120 of FIG. 12, but differs on the bonding method between the silicon wafer 1 and the metal wafer 2. The process 140 of FIG. 14 is different from the rest, as the functional layer is grown on top of the metallic substrate instead of wafer bonded. Here again, some of the steps presented in the process 90 of FIG. 9 could be integrated to produce a piezoelectric transducer. The process 160 of FIG. 16 differs from the process 130 because the tungsten substrate may be etched to form the mass 2 immediately after bonding underneath the silicon wafer 1. A SiO₂ or alumina (Al₂O₃) hard mask may be used for the dry plasma etching of the tungsten. In addition, a first cap wafer 9 may be bonded underneath the silicon wafer 1 after the mass 2 is etched. The cap 9 may be further used to support the partial assembly during the thinning and etching steps required to form the cantilever beam, similarly to step 12) of FIG. 11 (with top and bottom inverted in this example). Finally, a second cap wafer 9 may be bonded on top of the assembly to produce a sealed cavity.

Referring to FIG. 15, there is illustrated at 150 an inertial device resulting from some of the processes described above. For simplicity, the components such as the bond layer 3, mask layers 4 and 5, the piezoelectric material layer 6, the electrode layer 7, contact pads 8 and cap 9 are not illustrated, but may be present on the inertial device 150. The inertial device 150 has a proof mass 2 on a body made from the silicon wafer 1. The processes described above enable the defining of the various components of the inertial device 150 in the silicon wafer, including a frame 151. The frame 151 may have any appropriate shape, such as the square shape shown, but also including any polygon or arcuate shape. However, squares and rectangles are an efficient shape when the wafer 1 is diced into a plurality of inertial devices 150.

A cavity 152 is defined in the material of the wafer 1 so as to define a cantilevered portion or beam projecting inwardly from the frame 151 (a.k.a., anchor), and thus cantilevered relative to the frame 151. Consequently, the frame 151 and the cantilevered beam are monoblock silicon from the support wafer. The cantilevered beam may include a spring portion 153 for instance thinner than the frame 151, to reduce the stiffness of the cantilevered portion and expose its elastic deformation capability. According to an embodiment, the thickness of the spring portion 153 is between 10 and 50 μm. The proof mass 2 is at the cantilevered end of the cantilever beam to enhance the cantilever effect. Moreover, although the cantilever beam may have a uniform thickness, the cantilever beam may have a portion 154 of greater thickness on the side opposite the proof mass 2, to further increase the weight of the cantilevered end of the cantilever beam. In an embodiment, the footprint of the inertial device 150 is 1.0 cm² or less. The proof mass 2 occupies from 50% to 80% of the footprint of the inertial device 150. While not indicated in FIGS. 1, 6-14 and 16 of the processes to avoid an excessive number of reference numerals, the frame 151, cavity 152, the spring portion 153 and/or the portion 154 can be observed in these figures.

Tables 3 and 4 present summaries of the differences between the processes.

TABLE 3
Summary of the main characteristics of each process and the similarities/differences between each one

| | | Mass | Mass | |
|---|---|---|---|---|
| Process | Substrates | Integration | paterning | Comments |
| 10, 70 | 1 Metallic wafer (mass) | Adhesive wafer | Wet Chemical | 70 is a variation of 10 (more resistant masking |
| | 1 Silicon wafer (functional) | bonding | Milling | during first wet chemical etch) |
| 80, 90, | 1 Metallic wafer (mass) | Metallic bonding | Wet Chemical | 80 differs from 70 based on the bonding |
| 100 | 1 SOI wafer (functional) | | Milling | approach used and functional wafer used. |
| | | | | Beside this step, the other steps remain |
| | | | | the same. |
| | | | | 80 and 100 are identical, only to show how in |
| | | | | plane and out of plane devices can be |
| | | | | fabricated |
| | | | | 80 and 90 are very similar, but additional steps |
| | | | | are introduced to integrate a piezoelectric |
| | | | | material and a top electrode. |
| 110 | 1 Metallic wafer (mass) | Metallic bonding | Wet Chemical | 110 resembles 80, except a silicon wafer is |
| | 3 Silicon wafers (1 | | Milling | thinned down by lapping to fabricate the thin |
| | functional, 2 for capping) | | | beams instead of using the device layer of a |
| | | | | SOI wafer. |
| | | | | In addition, caps are integrated for wafer level |
| | | | | packaging. |
| | | | | No temporary carrier necessary |
| 120 | 1 Metallic wafer (mass) | Metallic bonding | Dry Etching | |
| | 1 Silicon wafers (functional) | | (Plasma) | |
| 130 | Metallic wafer (mass) | Fusion or anodic | Dry Etching | 130 resembles 120, but a different bonding |
| | Silicon wafer (functional) | bonding | (Plasma) | interface is used |
| 140 | Metallic wafer | Silicon growth on | Dry Etching | |
| | | metal substrate | (Plasma) | |
| 160 | 1 Metallic wafer (mass) | Fusion bonding | Dry | 160 resembles 110, but a different bonding |
| | 3 Silicon wafers (1 | | Etching | interface is used, whereas dry etching instead of |
| | functional, 2 for capping) | | (Plasma) | wet etching is also used to define the mass. |

TABLE 4
Summary of the advantages of each process version

| Version | Advantages |
|---|---|
| 10: Adhesive bonding v1 | Low bonding surface requirement |
| | Low bonding temperature |
| | Chemical wet etching of the mass can be made in |
| | batch |
| | Low cost functional substrate |
| 70: Adhesive bonding v2 | Same as 10 |
| | Hard mask on both sides enable long immersion |
| | during first wet etch of the mass wafer |
| 80, 100: Metallic bonding | Better control on bonding area |
| | Strong bond |
| | Resistant to higher temperature |
| | Chemical wet etching of the mass can be made in |
| | batch |
| | Improved uniformity across the wafer of the beam |
| | thickness by using an SOI wafer |
| 90: Metallic bonding, with Piezo | Same as 80, 100 |
| | Compatible with piezoelectric transducers (low power, |
| | low noise) |
| 110: Si thinning + cap bonding | Excellent control on bonding area |
| | Strong bond |
| | Resistant to higher temperature |
| | Chemical wet etching of the mass can be made in |
| | batch |
| | Includes a packaging strategy at the wafer level |
| | Low cost functional substrate |
| | No need for carrier wafer |
| 120: Si on metal v1 | Reduced number of steps |
| | Low cost functional substrate |
| | Better control on bonding area |
| | Strong bond |
| | Resistant to higher temperature |
| | Better control on the mass dimensions (vertical side |
| | walls) |
| | No need for carrier wafer |
| 130: Si on metal v2 | Reduced number of steps |
| | Low cost functional substrate |
| | Very strong bond |
| | Resistant to higher temperature |
| | Better control on the mass dimensions (vertical side |
| | walls) |
| | Potentially done at a lower temperature than 120 |
| | No need for carrier wafer |
| 140: Si on metal v3 | Reduced number of steps |
| | Only 1 substrate (no bonding, lower cost?) |
| | Resistant to higher temperature |
| | Better control on the mass dimensions (vertical side |
| | walls) |
| | No need for carrier wafer |
| 160 : Si thinning + cap bonding | Excellent control on bonding area |
| v2 | Strong bond |
| | Resistant to higher temperature |
| | Better control on the mass dimensions (vertical side |
| | walls) |
| | Includes a packaging strategy at the wafer level |
| | Low cost functional substrate |
| | No need for carrier wafer |

Detailed description of the processes
10: Process with adhesive wafer bonding version 1
This is the first version of the process and the version which has produced the first prototypes.
Problems with several steps are reported here. Solutions and alternatives are also exposed.

| Step | Description |
|---|---|
| 1 | The metallic wafer is polished to reduce its surface roughness. This can be accomplished |
| | by mechanical polishing or chemical-mechanical polishing (CMP). The wafer is then cleaned |
| | using a solvent (e.g. Remover 1165, acetone), an acidic (e.g. hydrofluoric acid, hydrochloric |
| | acid) or a basic solution (potassium hydroxide). The chemistry can vary depending on the metal |
| | which is used. Afterward, the wafer is rinsed in deionized water. The surface is hydrophilic |
| | if cleaned adequately. |
| 2 | A permanent masking material is deposited on the top surface of the metallic wafer and is |
| | selectively removed to define the future geometries of the masses. This material is selected |
| | to have a good etching selectivity to the etching agent compared to the metal wafer. In the |
| | proposed process, we have selected a layer stack of silicon dioxide (SiO2) and silicon nitride |
| | (Si3N4), because it resists well to the tungsten etchant. However, other materials, such as |
| | chromium (Cr), cured epoxy, polyimide or parylene could be used with the same solution. |
| | The SiO2 and Si3N4 can be deposited by plasma enhanced chemical vapor deposition (PECVD) |
| | or low pressure chemical vapor deposition (LPCVD). The LPCVD approach usually gives a |
| | more robust mask, with less defects or pin hole formation when it is immersed in the etching |
| | solution for long periods. |
| | A photolithography step and a CF4 based reactive ion etch (RIE) were used to pattern the |
| | SiO2/Si3N4 mask. The epoxy could be spin coated and UV patterned, while the chromium can |
| | be deposited by evaporation or sputtering and chemically etched after a photolithography |
| | step. |
| 3 | A temporary masking material is applied to the back of the metallic substrate. A thick |
| | photoresist is spun and patterned by photolithography. To support the prolonged immersion |
| | in the etching solution, the mask must be chemically resistant to it. The tungsten etchant |
| | is a mildly alkaline solution. An epoxy based resist is selected to fulfill this requirement |
| | (e.g. KMPR photoresist). |
| 4 | The metallic wafer is immersed for several minutes/hours in a liquid solution that selectively |
| | etches the metal and not the mask. The goal is the remove as much material as possible to |
| | partially define the masses, but keep enough so that all the masses remain mechanically |
| | connected. This approach has two advantages: First, all the masses can be carried simulta- |
| | neously, facilitating handling and eventually enabling alignment of all the masses in one |
| | operation (for parallel processing). Secondly, it reduces the rigidity of the metallic sub- |
| | strate and makes it slightly more compliant during and after bonding. The duration of the |
| | immersion is proportional to the wafer thickness. |
| | However, the photoresist delaminates from the surface after some time (approx. 2 hours) in the |
| | etching solution. Variation 70 is proposed to remove this problem. The solution we have used for |
| | this step is a warm buffered potassium ferricyanide (chemical notation: K3Fe(CN)6) based solution |
| | which is agitated to improve the etching uniformity. |
| | Warm hydrogen peroxide is also known to etch tungsten, and ozonated water may also be effective, |
| | but these etching agents may not be compatible with the photoresist. |
| | Finally, the photoresist is removed with a solvent only after the etch is completed. |
| 5 | A temporary photoresist mask is applied and patterned by photolithography on the top surface |
| | of the silicon wafer, which is the functional wafer. A deep reactive ion etching (DRIE) step |
| | is used to etch into the silicon material and define the mechanical support and spring patterns. |
| | Comb-like structures can also be etched during this step. These structures are used as capacitive |
| | transducers to convert the mass motion into an electrical signal (either for motion sensing or |
| | energy generation). |
| | Other etching methods, such as wet anisotropic or isotropic etching could also be used for this |
| | step, but the results would not be as good. These approaches would not provide the same degree |
| | of dimensional control (resolution) and the sidewalls would either be curved (isotropic etch) |
| | or at an angle (anisotropic etch). Moreover, vertical sidewalls are typically preferred for the |
| | comb and spring structures. Although traditional RIE could also be used to etch silicon, the |
| | silicon etch rate vs. resin selectivity is not sufficient for the depth of etching required to |
| | fabricate the beams (>10 μm) |
| | Finally, the photoresist mask is removed after the silicon is etched to the desired depth. |
| 6 | The metallic substrate is prepared for adhesive wafer bonding to the silicon wafer. An epoxy |
| | based resist (such as SU-8) is used as the adhesive, but other polymers could be considered |
| | (e.g. Benzocyclobutene (BCB)) as well. |
| | Due to the topologies created during the previous tungsten wet etch step, a roller based resist |
| | transfer method is used to apply the polymer on the patterned metallic substrate. A thick |
| | polymer layer is first spun on a support wafer. A Teflon coated roller is then rolled on the |
| | support wafer and immediately rolled over the metallic wafer to transfer part of the resist. |
| | Although the resist is not smooth nor uniform, the voids disappear when the adhesive flows and |
| | spread during the bonding process which occurs at an increased temperature. Moreover, the |
| | masses are not subject to stresses during the device operation and therefore the bond quality |
| | is not a critical parameter. The bond only needs to resist for the remaining process steps. |
| | It is important to control the thickness of the resist which is transferred to the metallic |
| | wafer. It the film is too thick, spreading in the periphery of the bonding area may occur and |
| | interfere with the adjacent structures. Conversely if this film is too thin, the quality of |
| | the bond interface may be poor. |
| | To avoid these problems, other intermediate layer bonding methods can be considered, such as |
| | using metal layers. In the MEMS field, eutectic and thermocompressive bonding are typically |
| | used. Contrary to eutectic bonding, thermocompressive bonding occurs in solid phase and |
| | therefore spillage is not a concern. Additionally, this type of bond can sustain much higher |
| | temperatures, offering more flexibility for the back-end processes. However, the surface |
| | roughness and cleanliness requirements are much stricter. These bonding approaches are proposed |
| | in variations 80, 90, 100, 110 and 120. |
| 7 | The metallic and silicon wafers are aligned by an optical method. Although infrared alignment |
| | is also an option typically offered, this approach is not compatible with a tungsten substrate |
| | because it is opaque to IR light as well as X-rays. Following the wafer alignment, the wafer |
| | stack is brought into a controlled atmosphere (vacuum, nitrogen or forming gas ambient) and |
| | both wafers are brought in contact. The stack is then heated up while pressure is applied to |
| | bond the two wafers together. Once the prescribed bonding time is elapsed, the pressure on the |
| | wafer stack is removed and it is cooled down progressively to minimize stresses. |
| 8 | The metal/silicon wafer stack is then immerged for a second round in the metal etching solution |
| | to remove the remaining exposed pats on the metallic substrate and release the masses. The |
| | masses are fully released once the metal between them is removed completely. Due to the |
| | isotropic and double sided etch, the side walls of the masses are curved and feature “knife |
| | edges. |
| | One solution to minimize this is to prolong the immersion in the etching solution to remove |
| | the excess material. A drawback of this approach is that it increases the minimum feature size |
| | which can be achieved by the method (thus reduces its spatial resolution). It is also quite |
| | difficult to control precisely and uniformly. |
| | To improve the patterns spatial resolution and the verticality of the sidewalls, dry plasma |
| | etching, using an SF6/C4F8 gas combination like the DRIE process for instance, could be |
| | considered. However, this method is serial in nature, while the wet etching approach can |
| | process wafers in batch (increased throughput). Other process versions which use this etching |
| | method are later proposed in variations 120, 130 and 140. |
| 9 | The silicon wafer is bonded to a temporary carrier, where the face with the masses is facing |
| | the carrier surface. For example a double sided polished glass/fused silica wafer (which is |
| | optically transparent) can be used. A solvent soluble transparent adhesive (such as Crystal |
| | bond 509) can also be used to bond the wafer to the carrier. In this example, the adhesive |
| | flows when heated (approx. 100°) and can be spread on both the glass carrier and over the |
| | masses and silicon surface. To remove voids and trapped air bubbles, the wafers are heated |
| | and put in vacuum. They are then put in contact with a gentle pressure while still heated to |
| | begin the bonding procedure. The temporary bond is finally completed by cooling down the stack |
| | to room temperature. The excess adhesive, which flows and spills outside of the wafer |
| | perimeter, is removed and cleaned up before further processing using a solvent (acetone). |
| 10 | If the carrier and adhesive are optically transparent and the adhesive is not soluble in water, |
| | further lithographic processes can be accomplished on the exposed silicon surface (back) to |
| | define an etching mask. However, a pre-defined hard mask could be deposited and patterned |
| | earlier in the process to avoid this step entirely. This approach is integrated in variations |
| | 80, 90 and 100. |
| | Once the mask is patterned, the beams are etched by DRIE. Like step 5, other methods could be |
| | used to etch silicon, but they have significant drawbacks. One of those is that potassium |
| | hydroxide (KOH), a typical anisotropic silicon etching chemical, may attack the temporary |
| | bonding interface, which would not occur with DRIE. |
| 11 | Finally, the devices are singulated using a dicer (with, for example, a resin based diamond |
| | blade). The temporary carrier is used to support each chip after dicing, but is removed |
| | afterward. The dies are released by dissolving the adhesive in a solvent (such as acetone) |
| | bath and are then cleaned, with deionized water for example. |

70: Process with adhesive wafer bonding version 2
All steps are identical to 10, with step 3 removed. Instead, step 2 adds a permanent mask on the back side of
the metallic wafer. This modification was introduced to solve the resist delamination issue discussed in 10,
step 4. With this modification, warm hydrogen peroxide or warm ozonated water might be a usable etching agent.
80/100: Process with metallic bonding

| 80/100 | 70 | |
|---|---|---|
| step # | equivalent | Comments/Description |
| 1 | — | The silicon wafer is replaced by a silicon on insulator (SOI) substrate to improve |
| | | the beam thickness uniformity across the wafer. |
| 2 | | Protection and adhesion layers are deposited on the top surface of the SOI wafer. |
| | | In this case the SiO2 and Si3N4 both acts as protection layers and electrical |
| | | insulation layers, while Si3N4 also serves as an adhesion and diffusion barrier |
| | | layer for the bonding metal which is deposited over it later (step 5). These |
| | | layers can be deposited by PECVD (lower temperature, lower quality) or LPCVD |
| | | (higher temperature, higher quality). |
| | | On the bottom surface, the material for an etching hard mask for the DRIE step |
| | | (step 13) is deposited. SiO2 is again used here (PECVD or LPCVD), but other |
| | | masking material could be considered, such as chromium or aluminum (sputtered or |
| | | evaporated). |
| 3 | — | The backside hard mask is patterned by lithography and then selective etching |
| | | (wet or dry). |
| 4 | — | The top side protection layers are patterned by lithography and selective etching |
| | | (wet or dry). |
| 5 | | The metallic layers for the wafer bonding are first deposited by sputtering or |
| | | evaporation, whichever gives the best surface finish. |
| | | First, a thin metallic layer is deposited on the Si3N4 to promote adhesion. Such |
| | | metal can be titanium, titanium nitride, tantalum, tantalum nitride or chromium. |
| | | The second metal is the effective bonding layer. For thermocompressive bonding, |
| | | it can consist of aluminum, copper or gold. For eutectic bonding, it can consist |
| | | of copper, tin, gold, lead, germanium, indium, silver or a combination of 2 or |
| | | more of these metals. These metals are patterned by selective metal etching (with |
| | | a resist mask) or by a lift-off process. The pattern defines the bonding area of |
| | | the mass, but can also define a seal ring around the device for potential |
| | | hermetic capping. |
| | | Another lithography process is conducted for deposition of another metal layer |
| | | to produce metallic electrodes pads in contact with the underlying doped silicon. |
| | | This metal, which is typically aluminum (but not restricted to) is patterned by |
| | | either lift-off or selective chemical etching. An additional metal, for example |
| | | chromium, might be deposited as well for additional protection of the metallic |
| | | pad (e.g. aluminum). |
| 6 | 4 | Although not shown on the diagram, a photoresist is first spread on the top |
| | | surface before the silicon etching. |
| 7 | 1 | — |
| 8 | 2 | — |
| 9 | 3 | — |
| 10 | | Following the metallic substrate etch, the bottom hard mask is polished by CMP |
| | | to produce a very smooth surface before deposition of the metallic bonding layer. |
| | | The metal deposition process before bonding is like step 5 (except without the |
| | | electrode metal). For thermocompressive bonding, the metal should be the same. |
| | | For eutectic bonding, the metal should be selected to produce a eutectic alloy |
| | | with the metal deposited on the silicon wafer. |
| 11 | 6 | A metallic instead of a polymer based bonding method is used. Process parameters |
| | | changes accordingly. |
| 12 | 7 | — |
| 13 | 8-9 | No lithography due to hard mask. |
| | | Etch is stopped on buried oxide layer. |
| 14 | 10 | — |

90: Process with piezoelectric material

| 90 | 80 | |
|---|---|---|
| step # | equivalent | Comments/Description |
| 1 | 1 | — |
| 2 | | A piezoelectric layer is deposited on top of the SOI device (top) layer. The |
| | | piezoelectric material is deposited by sputtering. This material can be aluminum |
| | | nitride (AIN), zinc oxide (ZnO), lead zirconate titatnate (PZT) or other |
| | | piezoelectric thin film materials. The first two materials are semiconductor, |
| | | which provide the advantage of increased compatibility with microfabrication |
| | | processes and semiconductor devices, although they have lower coupling properties. |
| | | Conversely, better coupling properties might be preferable in some applications, |
| | | which would justify the choice of PZT. |
| 3 | | Atop electrode is deposited on the piezoelectric material. Several metals could |
| | | be used, such as chromium, titanium, aluminum, molybdenum, tungsten, nickel, |
| | | platinum or gold. Ideally, this metal has low resistivity, low acoustic losses, |
| | | low surface roughness and a similar thermal coefficient of expansion to the underlying |
| | | piezoelectric layer. |
| 4 | 2 | — |
| 5 | 3 | — |
| 6 | 4 | — |
| 7 | 5 | This step is almost same as step 5 of 80, without the electrode deposition. |
| 8 | | A lithography step is realized for selective etching of the piezoelectric |
| | | material. The etch is done either in a liquid solution (wet etch) or in a plasma |
| | | (dry etch). The chemistry used depends on the piezoelectric material which is used. |
| 9 | 5 | The electrode deposition is done separately here, as described in step 5) of 80. |
| 10 | 6 | — |
| 11 | 7 | — |
| 12 | 8 | — |
| 13 | 9 | — |
| 14 | 10 | — |
| 15 | 11 | — |
| 16 | 12 | — |
| 17 | 13 | — |
| 18 | 14 | — |

110: Process with silicon thinning and cap bonding

| 110 | 80 | |
|---|---|---|
| step # | equivalent | Comments/Description |
| 1 | 1 | A silicon wafer is used instead of the SOI wafer |
| 2 | 2 | Like 2) in 80, protection and adhesion layers are deposited on the top |
| | | surface of the wafer. However, there is no deposition on the bottom surface. |
| 3 | 4 | — |
| 4 | 5 | — |
| 5 | 7 | — |
| 6 | 8 | — |
| 7 | 9 | — |
| 8 | 10 | — |
| 9 | 11 | — |
| 10 | 12 | — |
| 11 | — | A cap wafer is prepared by etching (wet or dry) a cavity (for example, in a |
| | | glass wafer or a silicon wafer), which is then bonded to the thinned silicon |
| | | wafer on which the masses have been bonded. A seal ring is also prepared on |
| | | the edges of the cavities to match with the patterns defined in step 4) of 110 |
| 12 | — | The functional wafer is thinned down by mechanical lapping and then polish |
| | | to smooth surface (mirror finish) from the back side. |
| 13 | — | After a lithographic step, the silicon is etched to produce the beam |
| | | geometry. Other processes could be realized just before this step to deposit |
| | | intermediate layers for bonding with a bottom cap to facilitate bonding. |
| 14 | — | A second cap wafer is prepared (like in 11) of 110). If the surface is very |
| | | smooth, a silicon-silicon fusion bonding is possible. Otherwise, an |
| | | intermediate layer is necessary to bond the cap. |

120: Silicon on metal process 1 (metal bonding, wafer thinning, dry etch)

| 120 | |
|---|---|
| step # | Comments Description |
| 1 | We start with a doped silicon wafer |
| 2 | A SiO2 layer is deposited on the back side (by PECVD, LPCD or thermal oxidation). This layer serves as |
| | an electrical insulation layer as well as an etch stop layer for the dry metal etching step. |
| 3 | A metallic bonding interface is deposited and patterned on the bottom of the silicon wafer. The choice |
| | of metal is like the other processes described above. |
| 4 | Same as 1) of 10 |
| 5 | Same as 3) of 120, although the choice of adhesion layer is made to adhere to tungsten instead of |
| | silicon nitride or silicon dioxide. |
| 6 | A hard mask is deposited on the back of the metallic substrate. The choice of material for the hard |
| | mask depends on the metal which is plasma etched and should provide good selectivity with the etching |
| | gas. For instance, etching tungsten can be realized by using SF6/C4F8 (like with silicon) and thus an |
| | aluminum or thick silicon dioxide could be deposited and etched to produce the hard mask. |
| 7 | The silicon and metallic wafer are bonded via the metallic intermediate layers. The bonding parameters |
| | are adjusted per the type (eutectic or thermocompression) and material combination used. |
| 8 | The top silicon wafer is thinned down and polished back to a mirror finished until it has the desired |
| | beam thickness. At this point, more steps could be realized to functionalize the surface (e.g. |
| | electrode depositions, addition of a piezo material) |
| 9 | A lithography is realized for the selective etching of the silicon which will pattern the beams and/or |
| | capacitive transducers. |
| 10 | The metallic substrate is etched deeply in a reactive plasma to free the cantilevers and release |
| | the masses. |

130: Silicon on metal process 2 (fusion bonding, wafer thinning, dry etch).

| 130 | 120 | |
|---|---|---|
| step # | equivalent | Comments Description |
| 1 | 1 | — |
| 2 | 2 | — |
| 3 | 4-5 | The metallic wafer is polished and cleaned. An intermediate layer is deposited |
| | | on top of the metallic wafer. |
| | | This layer, consisting of SiO2 instead of a metal, is also polished to a very |
| | | smooth finish (<1 nm rms), although other materials used in fusion bonding |
| | | could be used as well. |
| 4 | 7 | Fusion bonding is used instead of a metallic bond. The parameters are adjusted |
| | | accordingly. |
| 5 | 8 | — |
| 6 | 9 | — |
| 7 | 6 | — |
| 8 | 10 | — |

140: Silicon on metal process 3 (Si growth, dry etching)

| 140 | 130 | |
|---|---|---|
| step | equivalent | Comments Description |
| 1 | 3 | — |
| 2 | — | Instead of bonding a bulk silicon wafer, a polysilicon layer is grown on top |
| | | of the metallic substrate (by LPCVD). |
| 3 | 6 | — |
| 4 | 7 | — |
| 5 | 8 | — |

160: Process with silicon thinning and cap bonding (dry etching, fusion bonded)

| 160 | 110 | |
|---|---|---|
| step # | equivalent | Comments/Description |
| 1 | — | Like 1) in 130 |
| 2 | — | Like 2) in 130 |
| 3 | — | Like 3) in 130, except a hard mask (SiO2 or Al2O3) is also prepatterned on the |
| | | tungsten bottom face |
| 4 | — | Like 4) in 130, fusion bonding is used (in this example, SiO2 is used) |
| 5 | — | -The metallic substrate is etched deeply in a reactive plasma to form masses |
| 6 | 11 | Like 11) in 110, although the cap is bonded on the bottom instead- |
| 7 | 12 | — |
| 8 | 13 | — |
| 9 | 14 | — |

1. An inertial device comprising:
a frame,
a cantilever beam having a first end connected to the frame and a second end cantilevered relative to the frame, the cantilevered beam forming a spring portion between the first end and the second end, the cantilever beam having a support surface defining a support area,
wherein the frame and the cantilever beam are made from a support wafer, the support wafer being made of silicon, a thickness of the support wafer at the support area ranging between 10 μm and 800 μm; and
a mass bonded to the support surface of the silicon wafer at the support area, the mass being made of tungsten, a thickness of the mass being of at least 20 μm.

2. The inertial device according to claim 1, comprising a bond layer between the cantilever beam and the mass.

3. The inertial device according to claim 2, wherein the bond layer is one of an epoxy-based bond layer and a metallic bond layer.

4. The inertial device according to claim 1, further comprising a hard mask between the support area and the mass of tungsten.

5. The inertial device according to claim 4, wherein the hard mask has a layer of SiO₂.

6. The inertial device according to claim 4, wherein the hard mask has a layer of Si₃N₄.

7. The inertial device according to claim 1, further comprising a hard mask mounted to a surface of the mass away from the support area.

8. The inertial device according to claim 7, wherein the hard mask has a layer of SiO₂ or a layer of Si₃N₄.

9. (canceled)

10. The inertial device according to claim 1, further comprising a piezoelectric layer on the support surface of the cantilever beam.

11. The inertial device according to claim 10, further comprising a hard mask on a surface of the piezoelectric layer facing away from the support area.

12. The inertial device according to claim 11, further comprising an electrode layer on the surface of the piezoelectric layer facing away from the support wafer.

13. The inertial device according to claim 12, further comprising a contact connector through the hard mask and in contact with the electrode layer.

14. The inertial device according to claim 11, wherein the hard mask has a layer of SiO₂ or a layer of Si₃N₄.

15. (canceled)

16. The inertial device according to claim 1, wherein the support wafer is a silicon on insulator wafer having two layers of silicon separated by an insulator.

17. The inertial device according to claim 1, further comprising at least one cap mounted to the frame and encapsulating the mass.

18. The inertial device according to claim 1, wherein lateral surfaces of the mass project from the support surface in a non-perpendicular direction.

19. (canceled)

20. The inertial device according to claim 1, wherein a footprint of the mass ranges from 50% to 80% of the footprint of the frame.

21. (canceled)

22. The inertial device according to claim 1, wherein the spring portion of the cantilever beam is thinner than the frame and than a portion of the cantilever beam defining the support area.

23. The inertial device according to claim 22, wherein a thickness of the spring portion is between 10 and 50 μm.

24. The inertial device according to claim 1, wherein the frame and cantilever beam are monoblock from the support wafer.
